(19) United States
(12) Patent Application Publication
(10) Pub. No.: US 2015/0118012 A1
(43) Pub. Date: Apr. 30, 2015

(54) WAFER ENTRY PORT WITH GAS CONCENTRATION ATTENUATORS

(71) Applicant: Lam Research Corporation, Fremont, CA (US)

(72) Inventor: Jeffrey Alan Hawkins, Portland, OR (US)

(73) Assignee: Lam Research Corporation, Fremont, CA (US)

(21) Appl. No.: 14/069,220

(22) Filed: Oct. 31, 2013

(51) Int. Cl. F27D 3/00; B25J 11/00; H01L 21/677

(52) U.S. Cl. CPC F27D 3/0084; H01L 21/67739; B25J 11/0095
USPC 414/804; 414/805; 432/120

(57) ABSTRACT

The embodiments herein relate to methods and apparatus for inserting a substrate into a processing chamber. While many of the disclosed embodiments are described in relation to insertion of a semiconductor substrate into an anneal chamber with minimal introduction of oxygen, the implementations are not so limited. The disclosed embodiments are useful in many different situations where a relatively flat object is inserted through a channel into a processing volume, where it is desired that a particular gas concentration in the processing volume remain low. The disclosed embodiments use multiple cavities to serially attenuate the concentration of oxygen as the substrate moves into the processing volume of the anneal chamber. In some cases, a relatively high flow of gas originating from the anneal chamber is used. Further, a relatively low transfer speed may be used to transport the substrate into and out of the anneal chamber.

### BACKGROUND

In many semiconductor device fabrication processes, it is desirable to tailor the atmosphere surrounding a substrate during particular manufacturing steps. This atmospheric control helps minimize unwanted reactions and helps produce functioning and reliable devices.

One of the processes used in the manufacture of semiconductor devices is thermal annealing, which involves heating a partially fabricated integrated circuit to an elevated temperature for a period of time. Annealing is commonly performed after electrochemical deposition of copper in Damascene applications. Annealing is also commonly performed after other electrofill-related processes such as direct copper plating on semi-noble metals (e.g., ruthenium, cobalt, etc.), and removal of oxide from a seed layer before electrodeposition, and as a pre-treatment on non-copper barrier seed layers to improve plating.

In certain applications, the annealing process is most successful when the concentration of oxygen in the anneal chamber is minimized. One reason to minimize the oxygen concentration in this chamber is to avoid formation of unwanted oxides (e.g., copper oxide), which can interfere with metrology readings. For example, metrology readings taken on copper oxide may erroneously suggest that the deposited copper contains pits. This type of inaccurate finding may lead to the needless destruction/disposal of substrates that, in reality, are of acceptable quality. Another reason to reduce the amount of oxygen in an annealing chamber is that in some advanced processes such as direct copper deposition on a semi-noble metal, any oxide present on the copper may be fatal to the device. Therefore, there exists a need for a method/apparatus to minimize the oxygen concentration in an annealing chamber. This may be stated more generally as a need for a method/apparatus to minimize the concentration of a particular gas in a processing chamber.

### SUMMARY

Certain embodiments herein relate to methods of transferring a substrate from an outer environment into a processing chamber with minimal introduction of a gas of interest into the processing chamber. In some cases, the processing chamber is an annealing chamber and the gas of interest is oxygen. Other embodiments herein relate to a processing chamber having a thin entry slit for minimizing the introduction of a gas of interest into the processing chamber.

In one aspect of the embodiments herein, a processing chamber is provided. The processing chamber may have an entry slit for transporting a thin substrate from an outer environment to the interior of the processing chamber and/or from the interior of the processing chamber to the outer environment, where the entry slit includes an upper portion above the plane through which the substrate travels and a lower portion below the plane through which the substrate travels, and multiple cavities in fluid communication with the entry slit, where at least three cavities are provided along at least one of the upper portion and lower portion of the entry slit.

In some embodiments, the entry slit has a minimum height of between about 6-14 mm. In these or other cases, the entry slit may have a minimum height less than about six times greater than the thickness of the substrate. The substrate may be a 450 mm diameter semiconductor wafer in some cases. In other cases, the substrate may be a 200 mm semiconductor wafer, a 300 mm semiconductor wafer, or a printed circuit board. The embodiments may be used with other types of substrates, as well.

In certain implementations, at least two cavities are provided in a paired cavity configuration. An exhaust shroud may be provided in the entry slit, including a vacuum source in fluid communication with the entry slit. At least three cavities may be provided in an exhaust shroud. In these or other cases, at least three cavities may be provided in the entry slit at locations that are not part of an exhaust shroud. Two or more cavities may have the same dimensions in certain cases. However, the cavities may also have different dimensions, for example two or more cavities may have differing depths and/or widths and/or shapes. In some embodiments, at least one of the cavities has a depth between about 2-20 mm. The width of the cavities may also be between about 2-20 mm. A depth:width aspect ratio of the cavities may be between about 0.5-2, for example between about 0.75-1. In some embodiments, one or more of the cavities has a substantially rectangular cross section. However, one or more cavities may have a non-rectangular cross section. A distance between adjacent cavities on either the upper portion or lower portion of the entry slit may be at least about 1 cm.

The length of the entry slit may vary depending upon the desired concentration of the gas of interest in the processing chamber. In some embodiments, the entry slit is at least about 1.5 cm long, for example between about 1.5-10 cm long, or between about 3-7 cm long. This length may be measured as the distance between the outer environment and the processing chamber.

The processing chamber may be configured to maintain a maximum concentration of molecular oxygen below about 50 ppm, even during insertion and removal of the substrate. In some embodiments, the maximum concentration of molecular oxygen is maintained below about 10 ppm, or even below about 1 ppm. In various embodiments the processing chamber is an anneal chamber. The anneal chamber may include a cooling station and a heating station. The entry slit may further include a door having at least a first position and a second position. The first position may correspond to an open position and the second position may correspond to a closed position, or vice versa. The door may include a cavity that is in fluid communication with the entry slit when the door is in the first position.

In another aspect of the disclosed embodiments, a method of inserting a substrate from an outer environment into a processing chamber with minimal introduction of a gas of interest to the processing chamber is provided. The method may include inserting the substrate from the outer environment into an entry slit of a processing chamber, where the entry slit includes an upper portion above a plane through which the substrate travels, a lower portion below the plane through which the substrate travels, and a plurality of cavities in fluid communication with the entry slit, where at least three cavities are provided on at least one of the upper and lower portions of the entry slit; and transferring the substrate through the entry slit and into a processing volume of the processing chamber.

The method may also include opening a door in or on the entry slit when a substrate is being actively transferred through the door, and closing the door when no such transfer is occurring. In some cases, the method also includes flowing gas from the processing volume of the processing volume at an increased gas flow at a time when the door is open, and flowing gas from the processing volume at a decreased gas flow at a time when the door is closed. In some cases, the gas flow rate changes at the time that the door opens or closes. In other cases, the gas flow increases before a door is opened, and then is maintained at the increased flow rate until after the door is closed. In some implementations, the substrate may be removed from the processing chamber at a slower rate than was used to insert the substrate into the processing chamber. A speed used to insert and/or remove the substrate from the processing chamber may be relatively slow. For example, where the substrate is a 450 mm diameter wafer, the substrate may be transferred into the processing chamber over a period of at least about 2 seconds, for example between about 2-10 seconds, or between about 3-7 seconds, or between about 3-5 seconds.

The method may be used to maintain a maximum concentration of the gas of interest at a very low level. In some cases, the gas maximum concentration of the gas of interest is maintained below about 350 ppm, or below about 300 ppm, or below about 100 ppm, or below about 10 ppm, or below about 1 ppm. In certain embodiments, the processing chamber is an anneal chamber and the gas of interest is oxygen.

These and other features will be described below with reference to the associated drawings.

### BRIEF DESCRIPTION OF THE DRAWINGS

FIG. 1 shows a schematic of a multi-tool electroplating apparatus that may be used to implement the disclosed embodiments.

FIG. 2A shows a cross-sectional view of a substrate entry slit having a single pair of cavities.

FIG. 2B shows a cross-sectional view of a substrate entry slit having three pairs of cavities.

FIG. 2C shows cross-sectional views of different cavity shapes.

FIG. 3 shows a cross-sectional view of a substrate entry slit having a surface vacuum along with a single paired cavity.

FIG. 4 shows a flow chart for a method of annealing a substrate.

FIG. 5 provides a cross-sectional view of an anneal chamber according to various disclosed embodiments.

FIGS. 6 and 7 show close-up views of the entry slit of the anneal chamber shown in FIG. 5, with the door closed (FIG. 6) and with the door open (FIG. 7).

FIG. 8 illustrates an isometric cutaway view of the anneal chamber shown in FIGS. 5-7.

FIGS. 9 and 10 show close up versions of the isometric view of the anneal chamber as shown in FIG. 8, with the door closed (FIG. 9) and with the door open (FIG. 10).

FIG. 11 shows an alternative embodiment of a multi-tool electroplating apparatus that may be used to implement the disclosed embodiments.

FIGS. 12A-12D show various configurations of substrate entry slits.

FIG. 13 shows modeling results for the concentration of oxygen over time as a substrate is inserted through the substrate entry slits shown in FIGS. 12A-12D.

FIGS. 14A and 14B illustrate the stream lines within a substrate entrance slit for a single cavity case (FIG. 14A) and a multiple cavity case (FIG. 14B).

FIGS. 15A and 15B illustrate modeling results for oxygen concentration profiles in a substrate entrance slit for a single paired cavity case (FIG. 15A) and a multiple paired cavity case (FIG. 15B).

### DETAILED DESCRIPTION

In this application, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication thereon. A wafer or substrate used in the semiconductor device industry typically has a diameter of 200 mm, or 300 mm, or 450 mm. The following detailed description assumes the invention is implemented on a wafer. However, the invention is not so limited. The work piece may be of various shapes, sizes, and materials. In addition to semiconductor wafers, other work pieces that may take advantage of this invention include various articles such as printed circuit boards and the like.

In the following description, numerous specific details are set forth in order to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments. While certain embodiments may be described in terms of relative descriptors such as “left” and “right” or “upper” and “lower,” etc., these terms are used for ease of understanding and are not intended to be limiting unless otherwise specified. For example, although the substrate entry slit is described in terms of upper and lower portions, these elements may correspond to lower and upper portions, left and right portions, etc.

The disclosed embodiments relate generally to methods and apparatus for reducing the concentration of a particular gas in a processing chamber. While much of the discussion focuses on minimizing the concentration of oxygen in an annealing chamber, the invention is not so limited. The invention may also be used to reduce the concentration of other gasses and in other types of processing chambers.

Annealing is often performed to transform a less stable material into a more stable material. For example, in conventional Damascene processes, the electrochemically deposited copper has a relatively small grain size, as deposited (e.g., an average grain size between about 10-50 nm). This small grain size is thermodynamically unstable, and will morphologically change over time to form larger grains. If the partially fabricated integrated circuit is not annealed, the as-deposited grain structure will spontaneously convert to a more thermodynamically stable grain size over the period of a few days. The thermodynamically stable grain size (e.g., an average grain size between about 0.5-3× plated film thickness where film thicknesses range from 0.25-3 μm) is generally larger than the as-deposited grain size.

The unstable small grain sizes can cause a variety of problems. First, because the morphology of the deposited material is changing over time, this changing material presents an unstable foundation for subsequent processing. This is especially problematic because the timeframe for the morphological change is similar to or longer than the timeframe for fabricating the integrated circuit. In other words, if a substrate continues to undergo processing after a copper deposition, without performing an anneal process, the deposited copper will undergo morphological changes during the remaining fabrication steps. This unstable morphology is problematic in terms of producing reliable and uniform products. For example, a newly fabricated device may become defective after a morphological change is complete, or there may be significant variations from one substrate to the next.

Another problem arising from unstable small grain sizes is that the small grains can skew metrology results. In many implementations, the sheet resistance of newly deposited copper is measured in order to determine the thickness of the copper overburden and evaluate the uniformity of the deposition. This may be done with a four point probe, for example. Because the as-deposited small grains have a lower conductivity than the larger grains, the presence of freshly deposited/non-annealed copper can lead to unreliable conductivity measurements. This can also lead to inaccurate determinations of film thickness and uniformity.

In addition to the reasons above, it is desirable to convert the as-deposited metal to one having a larger grain size because the larger grains are easier to polish by chemical mechanical polishing, the process conventionally used to remove overburden. Further, the increased conductivity of the large grains is advantageous for device design.

In order to realize the large-grain benefits and avoid the problems related to unstable small grains, many semiconductor fabrication schemes use a thermal annealing process to rapidly convert the small grain copper to the desired large grain copper. In many applications, an annealing chamber will be provided to carry out this process. The annealing chamber may be a stand-alone unit, or may be integrated with an electroplating system or other multi-tool semiconductor processing apparatus.

Annealing methods and apparatus are further discussed and described in the following U.S. Patent documents, each of which is incorporated by reference herein in its entirety: U.S. Pat. No. 7,799,684, titled “TWO STEP PROCESS FOR UNIFORM ACROSS WAFER DEPOSITION AND VOID FREE FILLING ON RUTHENIUM COATED WAFERS”; U.S. Pat. No. 7,964,506, titled “TWO STEP COPPER ELECTROPLATING PROCESS WITH ANNEAL FOR UNIFORM ACROSS WAFER DEPOSITION AND VOID FREE FILLING ON RUTHENIUM COATED WAFERS”; U.S. Pat. No. 8,513,124, titled “COPPER ELECTROPLATING PROCESS FOR UNIFORM ACROSS WAFER DEPOSITION AND VOID FREE FILLING ON SEMI-NOBLE METAL COATED WAFERS”; U.S. Pat. No. 7,442,267, titled “ANNEAL OF RUTHENIUM SEED LAYER TO IMPROVE COPPER PLATING”; U.S. patent application Ser. No. 13/367,710, filed Feb. 7, 2012, and titled “COPPER ELECTROPLATING PROCESS FOR UNIFORM ACROSS WAFER DEPOSITION AND VOID FREE FILLING ON RUTHENIUM COATED WAFERS”; U.S. patent application Ser. No. 13/108,894, filed May 16, 2011, and titled “METHOD AND APPARATUS FOR FILLING INTERCONNECT STRUCTURES”; U.S. patent application Ser. No. 13/108,881, filed May 16, 2011, and titled “METHOD AND APPARATUS FOR FILLING INTERCONNECT STRUCTURES”; and U.S. patent application Ser. No. 13/744,335, filed Jan. 17, 2013, and titled “TREATMENT METHOD OF ELECTRODEPOSITED COPPER FOR WAFER-LEVEL-PACKAGING PROCESS FLOW.”

For certain annealing applications, it has been found that the annealing environment should contain little to no oxygen. Some applications require fewer than about 20 ppm oxygen, for example. The presence of oxygen in the annealing chamber may lead to oxidation of the deposited material (e.g., copper oxide forming on a copper surface). Any oxide present on the surface of the deposited material can be problematic. For example, in some applications the presence of any oxide material on a deposited surface can lead to failure of the device. One application where this may be an issue is direct copper deposition on a semi-noble metal. In this application, it may be necessary to maintain the concentration of oxygen lower than about 2 ppm. Further, the oxide can present substantial challenges, even where it does not lead to failure of the device. For example, oxide present on an annealed surface can lead a metrology tool to incorrectly conclude that the substrate surface contains pits. This type of inaccurate surface characterization can lead to the needless destruction of acceptable substrates. For these reasons, one of the goals of the disclosed embodiments is to design an anneal chamber entry port that minimizes the amount of oxygen present in the anneal chamber during processing. As noted above, the embodiments may also be used to minimize the amount of other gases present, and may also be implemented in other types of processing chambers.

A number of techniques have previously been used to minimize the concentration of oxygen in an anneal chamber. One technique involves using a load lock between a processing chamber (e.g., a deposition chamber/tool) and an anneal chamber. A load lock has at least two doors, one positioned between the load lock and an outer environment, and a second one positioned between the load lock and an anneal chamber.

To process a substrate in the anneal chamber with minimal introduction of oxygen, several steps may be undertaken in sequence. First, the substrate is introduced to the outer environment. The outer environment may be an open air environment in some cases. In other cases, the outer environment is the inside of a semiconductor processing tool (e.g., a deposition chamber, a vacuum transfer module, an atmospheric transfer module, etc.). It should be noted that the term “outer” refers to an environment that is outside the load lock and anneal chamber. Next, the door between the load lock and the anneal chamber remains closed while the door between the load lock and the outer environment is opened. The substrate may then be transferred into the load lock. After the wafer is transferred, the door between the load lock and outer environment is closed. At this point, all of the load lock doors should be closed. Next, the load lock may be evacuated and/or swept with a process gas to ensure that substantially all of the oxygen is removed. The door between the load lock and the anneal chamber may then be opened, and the substrate transferred into the anneal chamber for processing in an environment that is substantially free of oxygen.

While load locks provide a reliable approach to minimizing the concentration of oxygen in the anneal chamber, they suffer from certain disadvantages. First, load lock systems are expensive to install and maintain. Second, load locks require extra processing steps that slow down the production process. Third, this slowdown results in decreased throughput and profit.

Another approach to the problem involves providing a strong positive pressure inside the anneal chamber. One way to implement this approach is to use a high gas flow rate originating inside the anneal chamber. As gas is introduced into the anneal chamber and pressure begins to build up, gas is pushed out through, e.g., the entrance port on the anneal chamber. This approach helps minimize the amount of oxygen that enters the anneal chamber through the substrate entrance port, as any oxygen present in this region is swept out of the chamber with the rapidly exiting gas.

One drawback to the positive pressure approach is that it results in the transfer of processing gases present in the anneal chamber to other environments where these processing gases may be harmful or otherwise cannot be tolerated. In many cases, the gas in the anneal chamber is inert or reducing. In certain embodiments, the gas in the anneal chamber is forming gas containing nitrogen and hydrogen. Forming gas is particularly useful because it helps provide a reducing atmosphere to help overpower the oxidizing effect of low oxygen concentrations. For many applications, it is unacceptable to have hydrogen gas exit from a process device (e.g., an anneal chamber) into a fabrication facility, or into other parts of a processing tool. In these applications, the positive pressure approach may not be a viable option.

The embodiments herein approach the problem in a different way. In particular, the disclosed embodiments focus on the use of multiple cavities or other structures interposed along the length of a substrate entry slit of an anneal chamber to modify the hydrodynamic conditions in this area. The entry slit may also be referred to as an entry port or channel. In effect, the cavities operate to consecutively attenuate the concentration of oxygen as the substrate moves farther into the anneal chamber. In some cases, it is believed that oxygen is transported into the anneal chamber on a boundary layer on the substrate. The modified hydrodynamic conditions resulting from the disclosed embodiments may remove the oxygen that is carried along on/with the substrate surface. In some designs, turbulence or other hydrodynamic scouring may be employed to further reduce the flow of oxygen into the interior of the anneal chamber. In some embodiments, one or more of the cavities are coupled with vacuum sources to further reduce the amount of oxygen in the anneal chamber.

As used herein, the term entry slit means a channel through which a substrate travels before entering a processing chamber. Typically, an entry slit will be relatively short in terms of height, on the order of about 6-14 mm. This height is designed to be tall enough to accommodate a substrate and the robotic arm used to transfer the substrate, but short enough to help minimize oxygen flow into the anneal chamber. Semiconductor substrates are fairly thin, for example between about 0.5-1 mm. Printed circuit boards are about ten times thicker and may have tall devices or other complex structures that require additional slit height. In the context of oven cures, the slit height may be much larger. In the context of an anneal chamber, the entry slit is generally positioned between an outer environment and a cooling portion of the anneal chamber. In some embodiments, a separate piece (e.g., an exhaust shroud) may be aligned with/attached to the annealing chamber entrance. Where this separate piece effectively extends the channel through which the substrate travels before entering the processing portion of the anneal chamber, this separate piece is considered to be part of the entry slit (and not part of the outer environment). This is explained further below. In some embodiments, an anneal chamber includes both an entry slit and an exit slit, which in some cases may be positioned on opposite ends of the anneal chamber. Each of the entry and exit slits may include a door. The teachings herein regarding an entry slit also apply to an exit slit. In this case, the direction of gas flow originating from the processing chamber may be reversed between the time that a substrate enters the chamber and the time the substrate exits the chamber. Typically, only a single door will be open at a given time.

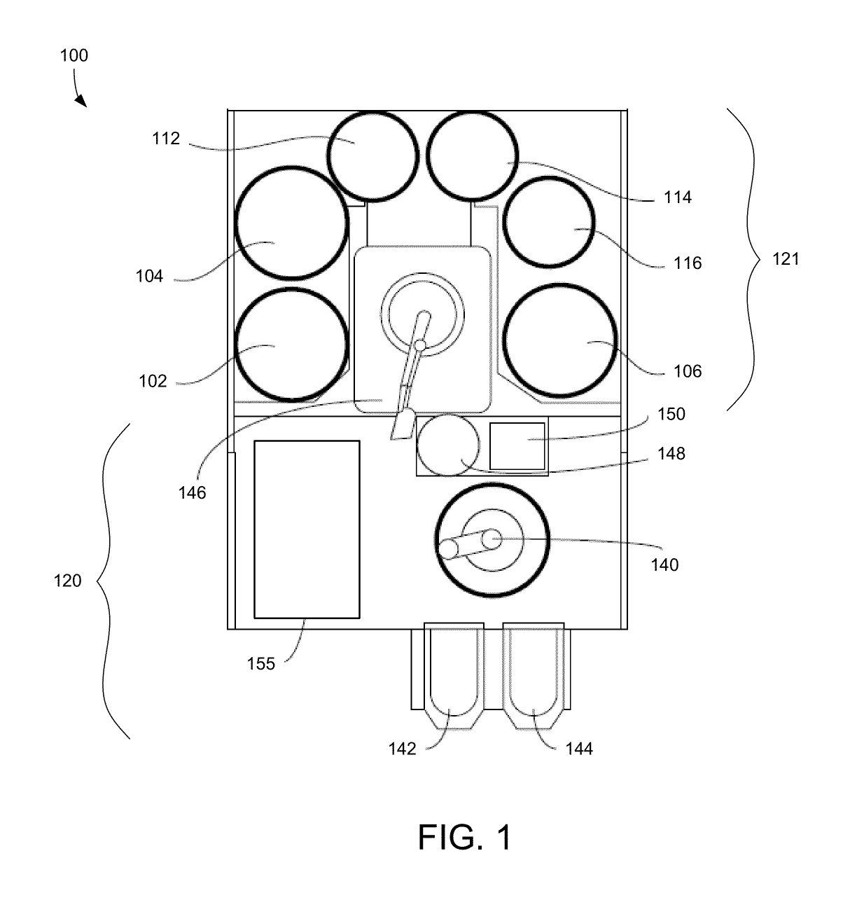

FIG. 1 provides a top down view of one embodiment of a multi-tool semiconductor processing apparatus 100 that may be used to implement the disclosed embodiments. The electrodeposition apparatus 100 shown in FIG. 1 includes a front end 120 and a back end 121. The front end 120 includes a front end hand-off tool 140 for transferring a substrate between different portions of the apparatus. The front end 120 also includes front opening unified pods (FOUPs) 142 and 144, as well as an annealing chamber 155, and transfer station 148. The transfer station 148 may include an aligner 150. The back end 121 of the apparatus 100 includes the rest of the electroplating hardware, including three separate electroplating modules 102, 104 and 106, and a stripping module 116. Two separate modules 112 and 114 may be configured for various process operations, for example spin rinse drying, edge bevel removal, backside etching, and acid cleaning of substrates after they have been processed by one of the electroplating modules 102, 104 or 106. These modules 112 and 114 may be referred to as post-electrofill modules (PEMs). In some embodiments, module 116 is a PEM instead of a stripping module. A back end hand-off tool 146 may be used to transfer the substrate as needed, for example between the transfer station 150 and an electroplating module 102. The hand-off tools 140 and 146 may also be referred to as robots or transfer robots.

In a typical embodiment, a wafer is placed in a FOUP 142 or 144, where it is picked up by front end hand-off tool 140. The hand-off tool 140 may deliver the substrate to the aligner 148/transfer station 150. From here, the back end hand-off tool 146 picks up the wafer and transfers it to an electroplating module 102. After an electrodeposition process takes place, the back end hand-off tool 146 may transfer the substrate to module 112 for post-deposition processing. After this processing occurs, the back end hand-off tool 146 may transfer the substrate back to the transfer station 150. From here, the front end hand-off tool 140 may transfer the substrate to the anneal chamber 155. Next, after annealing is complete, the front end hand-off tool 140 may transfer the substrate to the FOUP 142, where it may be removed.

The substrate may be exposed to atmospheric conditions at various points during the fabrication process in the electroplating apparatus 100. For example, in some embodiments, all the space outside of the individual modules 102, 104, 106, 112, 114, 116 and 155 is at atmospheric conditions. In other embodiments, the back end 121 may be under vacuum, while the front end 120 is at atmospheric conditions. Further, in some cases the individual electroplating modules 102, 104 and 106 and/or PEMs 112 and 114 may be under atmospheric conditions. Whatever the exact setup, it is common for the area immediately outside of the anneal chamber 155 to be exposed to atmospheric (or other oxygen-containing) conditions.

As explained above, it is desirable in certain applications to minimize the concentration of oxygen inside an annealing chamber. This minimization requires reducing the amount of oxygen that enters the anneal chamber each time a substrate is inserted into or removed from the chamber.

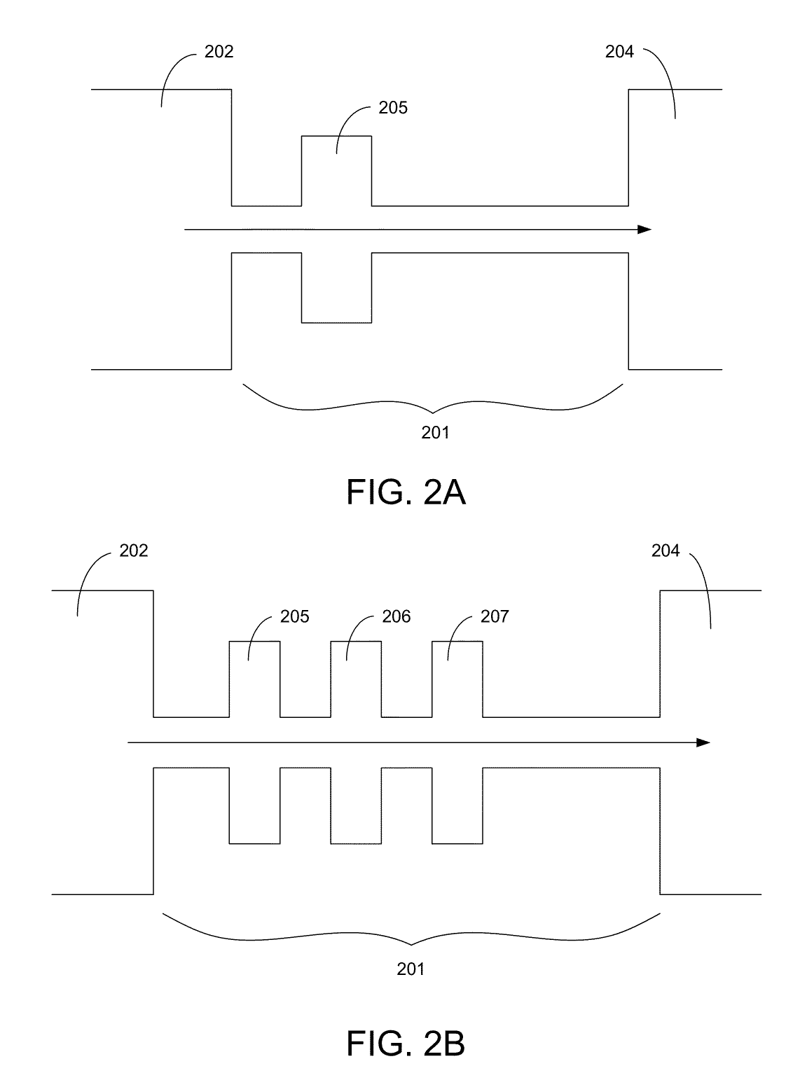

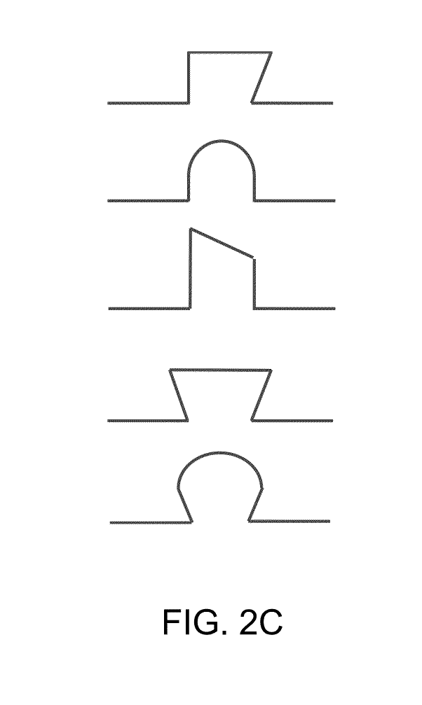

FIG. 2A provides a simplified view of a substrate entry slit 201 (also referred to as an entry port) that may be used to minimize the concentration of oxygen in an anneal chamber 204. In FIG. 2A, the entry slit 201 is positioned between an outer environment 202 and an anneal chamber 204. The outer environment 202 may be the interior of a multi-tool semiconductor electroplating apparatus, for example. The entry slit 201 includes a cavity 205 on the top and bottom regions of the slit 201. The arrow in FIG. 2A represents the path that a substrate travels as it moves from the outer environment 202 into the anneal chamber 204. As the substrate moves along this arrow, it carries along some amount of oxygen, typically in a boundary layer close to the substrate surface. The cavity 205 helps attenuate the concentration of oxygen as the wafer moves farther into the anneal chamber 204.

Another factor contributing to the oxygen concentration attenuation is the length of the slit 201. Longer slit lengths are better at reducing the oxygen concentration in the chamber 204. The optimal length of the entry slit is affected by geometric considerations and hydrodynamic conditions inside the slit. The Peclet number, a dimensionless ratio relating the advective transport rate to the diffusive transport rate, is useful in determining the optimal length of the entry slit. In some embodiments, molecular oxygen transport associated a wafer's passage through the entry slit is characterized by a Peclet number of between about 10-100. In some embodiments, the length of slit 201 is between about 1.5-10 cm, for example between about 3-7 cm. The slit length depends on desired O₂ level in the anneal chamber, the gas velocity, and non-ideal behaviors such as insertion/removal of wafers, non-uniform gas flow along the width of a slit, edge effects and external air currents that impinge upon the opening. A relatively high acceptable O₂ level within the chamber (e.g. >100 ppm) with small slit height (6 mm) and high gas velocity (12 inch/sec) could be fairly short in length, for example less than about 1 mm (e.g., less than about 0.5 mm). A 2 ppm acceptable O₂ level with 14 mm slit height and 1 inch/sec gas flow would need a longer slit, for example about 10 mm long or less (e.g., about 8 mm long or less).

A cavity is a deviation from a plane or nominally flat region substantially parallel to a surface of a work piece (wafer) as it moves through the entrance slit. Without a cavity, the entrance slit would be primarily defined by two nominally flat surfaces, each substantially parallel to a face of the wafer during transport through the slit. One such surface would be to one side of the wafer and the other such surface would be to the other side of the wafer (e.g., above and below the wafer). A cavity presents an indentation in one otherwise nominally flat surface of the entry slit. The indentation direction points away from the position of a wafer in the entrance slit. FIGS. 2A-B, 3, 5-10, 12B-D, 14A-B and 15A-B depict examples of cavities.

A cavity may have any one of many different shapes and/or sizes. In certain embodiments, a cavity has a “width” (dimension in a direction substantially parallel to the face of the wafer) and a “depth” (dimension in a direction away from the face of the wafer). It is expected that many different cavity geometries may be used, including different heights, widths, and shapes of cavities. In some embodiments, the cavities may not be rectangular. FIG. 2C presents cross-sectional views of different exemplary cavity shapes.

The geometry of the cavities also has an effect on their ability to minimize oxygen concentration in the anneal chamber. In some embodiments, one or more cavities have a depth between about 2-20 mm, for example a depth between about 5-8 mm, as measured from the top of a cavity to the bottom of a cavity. In these or other embodiments, the cavities may have a width (measured in the left-right direction in FIG. 2A) between about 2-20 mm, for example between about 4-10 mm. The cavities may have an aspect ratio (height:width) between about 0.5-2, for example between about 0.75-1. The space between consecutive cavities may also affect the effectiveness of the cavities. Spacing between cavities does not need to be any greater than that required for airflow turbulence to subside and stream flow lines to become smooth, at which point another pressure drop will cause disruption of flow from the wafer surface. In some embodiments, the length between cavities is between about 0.25-2× the cavity width, for example between about 0.5-1× the cavity width.

FIG. 2B presents a simplified view of an alternative design of a substrate entry slit 201. Here, additional cavities 206 and 207 are included to serially/consecutively attenuate the concentration of oxygen. In other words, the concentration of oxygen in the first cavity 205 is higher than the concentration in the second cavity 206, which is higher than the concentration in the third cavity 207. This serial attenuation allows the concentration of oxygen in the anneal chamber 204 to be reduced to an extremely low level. In conventional designs, the anneal chamber experiences about 20-30 ppm oxygen at steady state operation, and transient peaks of about 400 ppm oxygen during insertion/removal of a substrate. With the improved designs disclosed herein, the oxygen levels (both steady state and peak) are lower than these values. For instance, the oxygen concentration in the anneal chamber at steady state may be less than about 15 ppm, for example less than about 5 ppm, less than about 1 ppm, or even less than about 0.1 ppm. Experimental results showed a steady state oxygen concentration of less than 0.1 ppm, which was the lower limit for detector accuracy. The transient peak oxygen concentration in the chamber may be less than about 300 ppm, for example less than about 100 ppm, or less than about 10 ppm, or less than about 1 ppm. Experimental results have shown that the disclosed embodiments were able to achieve transient peak oxygen concentrations off less than 1 ppm.

In some embodiments, there may be a vacuum source coupled with the top and/or bottom cavities 205, 206 and/or 207. This vacuum helps remove oxygen brought in with the substrate, and also helps prevent any processing gases (e.g., forming gas) from exiting into the outer environment 202. The vacuum may be coupled to one or more of the cavities. In some cases, the vacuum source is applied through an exhaust shroud. The exhaust shroud may be implemented within the substrate entrance port, or just outside of it, for example attached to/aligned with the entrance port.

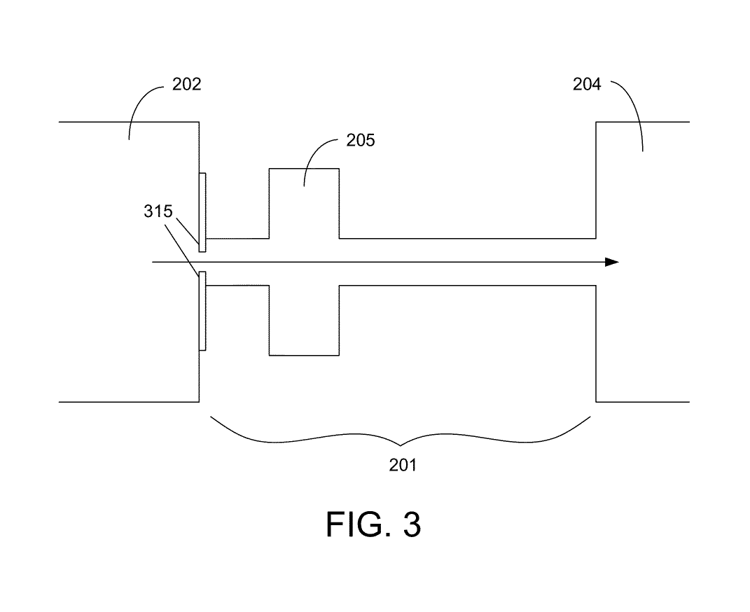

In certain implementations, one or more additional hydrodynamic elements are included to further attenuate unwanted gas concentration in the processing chamber. In one example, a hydrodynamic element may be referred to as a surface vacuum. FIG. 3 shows a substrate entry slit 201 having a surface vacuum 315 positioned proximate the entrance. The surface vacuum 315 includes two nozzles coupled with vacuum sources. The nozzles may be shaped as narrow rectangular nozzles that extend across the width of a substrate passing under/over them. In another embodiment, many nozzles/holes are used in combination to extend across the width of a substrate in a row or closely packed array. The vacuum pulls gas through the nozzles, in a similar fashion to the exhaust shroud. However, the surface vacuum is distinct from the exhaust shroud in that it is positioned much closer to the substrate surface. While the exhaust shroud applies a vacuum to the top and bottom surfaces of the cavities, the surface vacuum 315 acts much closer to the surface of the substrate. This is especially useful in drawing off the oxygen present on the boundary layer of the substrate. In some embodiments, the distance between the substrate surface and the edge of the surface vacuum may be between about 1-2 mm. In contrast, the distance between the substrate surface and an exhaust shroud (i.e., the proximal end of a cavity) may be between about 4-5 mm. In some cases the surface vacuum may act on only a single surface of the substrate (e.g., only a top surface), though in other cases the surface vacuum acts on both surfaces of the substrate, as shown in FIG. 3. The surface vacuum may be implemented as a separate element in the entrance slit, or it may be implemented as part of a cavity. In one embodiment, the surface vacuum is positioned between two cavities that are very close together, such as between cavities 602a and 602c of FIG. 6. In this embodiment, the surface vacuum separates the cavities in the exhaust shroud.

The flow through the surface vacuum affects the surface vacuum's ability to attenuate oxygen concentration. Lower total volumetric flow rates are preferable. If the flow is too high, it may cause the surface vacuum to pull air in from the outer environment. The closer the edge of the surface vacuum is to the surface of the substrate, the better the performance of the surface vacuum. A short distance between the surface vacuum and the substrate is beneficial at least because it promotes a higher vacuum pressure, a higher velocity for the oxygen scrubbing, and lower total flow.

Certain processing parameters can help further reduce the concentration of oxygen in the anneal chamber. As mentioned above, in certain embodiments, there is a flow of gas originating from the interior of the anneal chamber and exiting, at least partially, through the substrate entry port and/or vacuum source. In many cases this gas is forming gas, though other processing gases may be used as well. In the context of FIG. 2B, the arrow notes the direction of substrate movement through the slit as it is inserted into the anneal chamber. The gas flow is opposite the direction of this arrow.

In certain embodiments, a door is included in the entry slit. In some designs, a door will rotate or slide upwards and/or downwards to open. The door may be positioned at an entrance to the entry slit, or within the entry slit. Where the door is within the entry slit, it may be positioned between cavities (i.e., the leading edge of a substrate may pass over/under one or more cavities before reaching the door, and may also pass over/under one or more cavities after reaching the door). The door may be open when a substrate is actively moving through it, and closed when there is no substrate actively passing through, such as when the wafer is being processed in the chamber. In some cases, the door may be closed as soon as the substrate is through the door. In other cases, the door may remain open for a period of time to allow the relatively high gas flow to remove oxygen from the anneal chamber. In these cases, the door may remain open for a period between about 1-10 seconds after the substrate has passed through the door.

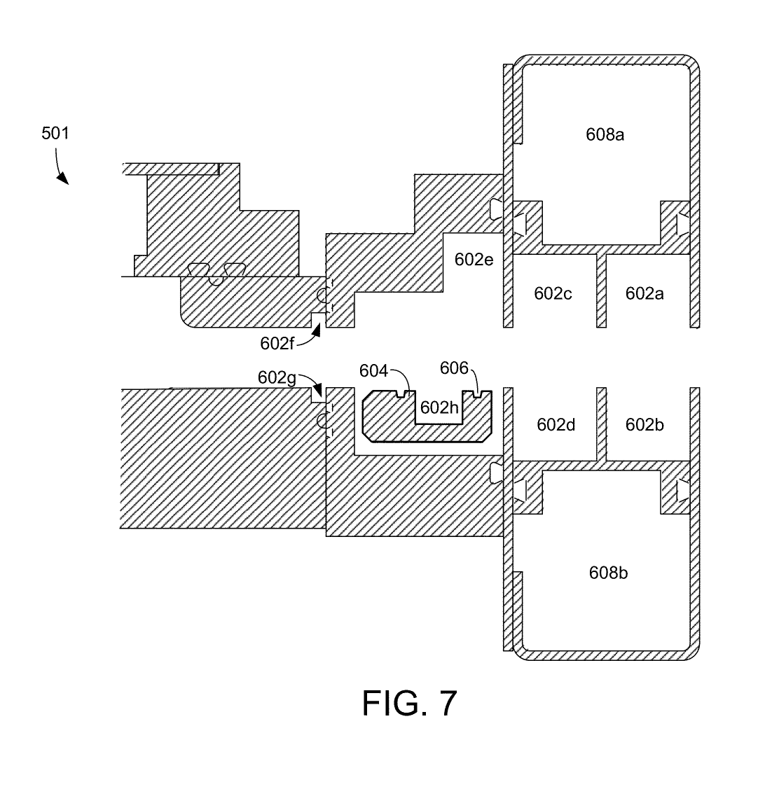

In some embodiments the door includes a cavity, such that when the door is rotated open, it provides an additional cavity in the entry slit for attenuating the concentration of oxygen. This is shown in FIG. 7, which is discussed further below. In other embodiments where the door slides up or down to open, the door may be slid up/down farther than necessary in order to create an additional cavity. The flow of gas through the entry slit may change significantly depending on whether the door is open or closed, with the gas flow being significantly higher when the door is open. In some cases, the gas flow is increased or maintained at a high level during a period that starts before the door is opened and ends after the door is closed. This period may extend before and/or after the period that the door is open by about 1-10 seconds.

The linear gas velocity through this slit helps determine the level of oxygen in the anneal chamber. Higher linear gas velocities provide improved oxygen minimization. In some embodiments, the linear gas velocity through the entry slit is between about 5-30 cm/sec, or between about 10-20 cm/sec. In these or other cases, the linear gas velocity may be at least about 5 cm/s, or at least about 15 cm/sec, or at least about 17 cm/sec. In a particular embodiment, the linear gas velocity through the slit is about 16.8 cm/sec. These values relate to those used for a 450 mm diameter substrate, and may be scaled accordingly. The velocities will scale with the height/width of a slit, which indirectly scale with the size of the substrate.

Another factor which helps minimize the oxygen level in the anneal chamber is the speed at which a robot/hand-off tool inserts the substrate into and through the entry slit. Generally, slower robot speeds are beneficial for achieving minimal oxygen levels. However, for throughput reasons, it is often desirable to insert and remove the substrate at faster speeds. This consideration is especially important as the industry moves toward 450 mm substrates, which often require longer processing times. Thus, there is a tradeoff between achieving the lowest possible oxygen concentrations in the chamber on the one hand, and throughput on the other. In certain embodiments, the time it takes for a robot/hand-off tool to insert a wafer is between about 2-10 seconds, or between about 3-7 seconds, or between about 3-5 seconds. These values represent the times for inserting a 450 mm diameter substrate, and may be scaled accordingly. For example, for a 300 mm substrate, the entry time may be between about 0.5-3 seconds, for example about 1 second. A number of considerations may go into scaling the timeframe for substrate insertion, including the substrate diameter, any acceleration/deceleration of the robot, etc.

Another aspect that influences the concentration of oxygen in the anneal chamber is the number of cavities used. Generally, entry slits having higher numbers of cavities are more successful in attenuating the oxygen concentration. In measuring the number of cavities in a particular design, both top and bottom cavities should be counted. For example, FIG. 2A shows an entry slit having two cavities, and FIG. 2B shows an entry slit having six cavities. The term “paired cavity” may also be used to describe two cavities that are aligned with one another in a vertical direction (e.g., a top cavity aligned with a bottom cavity). As such, it can also be said that FIG. 2A shows an entry slit having a single paired cavity, and FIG. 2B shows an entry slit having three paired cavities. In some embodiments, the paired cavities are aligned such that the center of the cavities are aligned with one another. The cavities of a paired cavity may also be the same height and/or width, or they may have different height and/or width. It need not be the case that the cavities are paired (e.g., top and bottom cavities may be offset from one another), or that the total number of cavities is even.

Also, where a structure such as an exhaust shroud is aligned with and/or attached to the entrance of the entry slit (such that the structure is outside of the entry slit, effectively extending the channel through which the substrate travels to enter the anneal chamber), this aligned structure is considered to be part of the entry slit, and any cavities included in such aligned/attached structures are counted as being part of the entry slit. In other words, while the cavities may be implemented on different parts of the apparatus, any cavities that are in the channel through which the substrate travels on its way from an outer environment to the anneal chamber are counted as being part of the substrate entry slit.

In some embodiments, the number of cavities is at least about 5, at least about 6, or at least about 8. The cavities may be distributed along the top and/or bottom of the entry slit. For example, in one embodiment there are at least about three cavities distributed along either the top or bottom of the entry slit. In some cases, there are at least three paired cavities.

In some embodiments, different conditions are used during insertion of the substrate into the anneal chamber vs. during removal of the substrate from the anneal chamber. Typically, oxygen concentration levels are higher during removal than during insertion of a substrate. One reason for this may be that as the substrate is removed, a suction force is temporarily created in the space where the substrate was originally positioned. Gas, including oxygen, may rush to fill in this area as the substrate is removed from the anneal chamber. This problem may be addressed by removing the substrate at a slow speed. In some embodiments, the substrate is removed through the entry slit at a slower rate than it is inserted. In terms of the average linear transfer speeds, the insertion speed may be at least about 10-30% faster than the removal speed. This may correspond to an average removal speed of less than about 9 cm/s, or less than about 5 cm/s.

The disclosed techniques may achieve a number of benefits. As an example, the disclosed embodiments are able to realize an oxygen concentration in the anneal chamber that is less than about 1 ppm, even during substrate introduction and removal. This low oxygen concentration is ideal for many anneal applications. Further, the low concentration may lead to faster processing overall, since the anneal chamber needs less time (or no time) to perform a pre-anneal purge to reduce the oxygen concentrations to acceptable levels. In many embodiments, the use of cavities allows the anneal chamber to achieve the disclosed oxygen concentrations without any dedicated pre-anneal purge. Another potential advantage of the embodiments herein is that they are less sensitive to outside air currents than conventional designs. Oftentimes, a transfer robot will create air currents as it moves substrates between different portions of a multi-tool apparatus. By providing cavities in the substrate entry slit, along with optionally using a relatively slow robot transfer speed, a relatively high linear gas flow velocity through the slit, and/or a door, these outside air currents are much less likely to affect the inside of the anneal chamber.

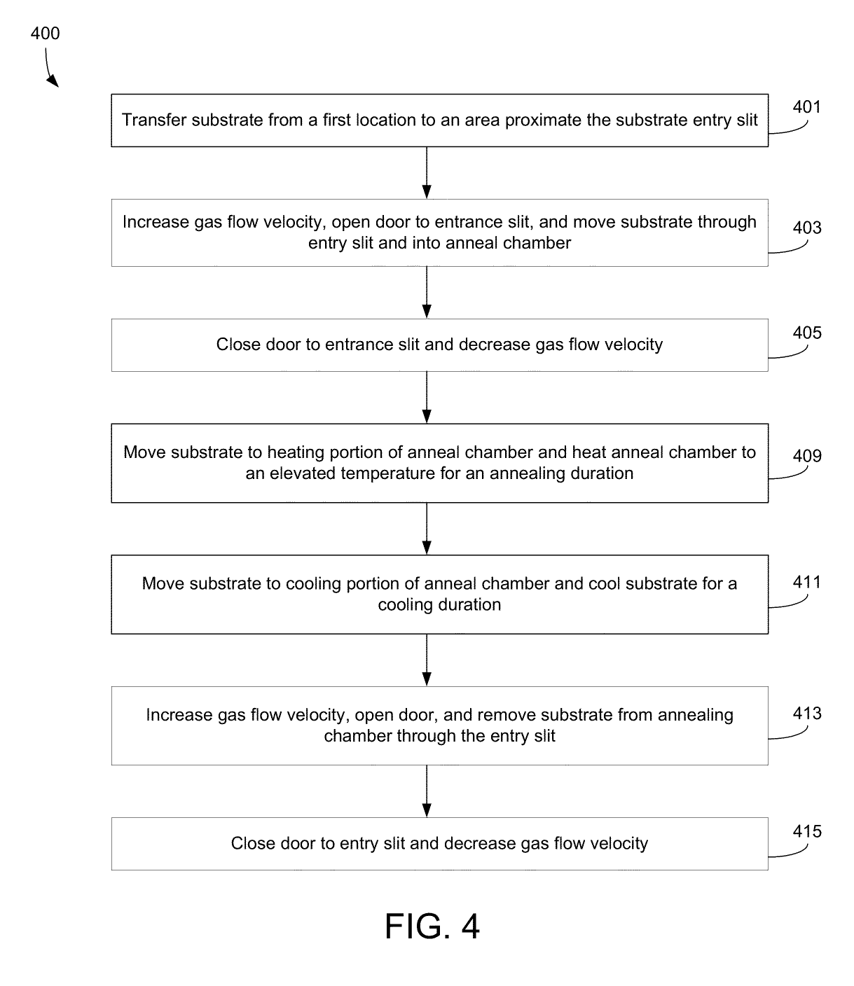

FIG. 4 presents a flowchart for a method of annealing a substrate according to certain embodiments herein. The method 400 begins at operation 401, where a substrate is transferred from a first location to an area proximate the substrate entry slit. In many cases the first location may be an electrodeposition module, a post-electrofill module, or any other portion of a multi-tool substrate processing apparatus. Alternatively, the first location may not be part of a processing apparatus, and the annealing chamber may be a stand-alone unit. At operation 403, the gas flow velocity is increased, a door between the outer environment and the anneal chamber is opened, and the substrate is moved through the entry slit at a relatively slow travel speed into the processing volume of the anneal chamber. The entry slit will have multiple cavities in many embodiments. After the substrate has passed through the entry slit, the door may be closed and the gas flow velocity may be decreased at operation 405. As explained above, the gas flow velocity may be maintained at a much higher level when the door is open compared to when it is closed, or during a period surrounding the time that the door is open (i.e., gas flow may increase before the door is opened and decrease after the door is closed). An optional pre-anneal purge may be performed at this time, though in many embodiments it is not necessary. At operation 409, the substrate is moved to a heating portion of the anneal chamber. The wafer is then heated to an elevated temperature for an annealing duration. In many implementations, the wafer is heated to a temperature between about 125-425° C. The ideal anneal time will depend on the particular application, and in many cases is between about 150-250° C., for example about 180° C. The anneal time will also depend on the particular application, and is often between about 60-400 seconds.

After annealing is performed, the substrate is moved in operation 411 to a cooling portion of the anneal chamber. Here, the substrate is optionally cooled for a cooling duration, for example between about 30-60 seconds. Next, the gas flow velocity is increased, the door is opened, and the substrate is removed from the annealing chamber in operation 413. The door to the entry slit is then closed in operation 415 and the gas flow is decreased to help minimize gas consumption while maintaining a low oxygen concentration in the anneal chamber.

It should be noted that several of the operations outlined in FIG. 4 are optional. For example, in some embodiments, the wafer entry slit does not include a door. Where this is the case, several operations may be simplified or eliminated. For example, operations 403 and 413 would simplify to operations in which the substrate is moved through the entrance to the entry slit, and operations 405 and 415 would be eliminated. Likewise, the cooling operation may be eliminated at operation 411.

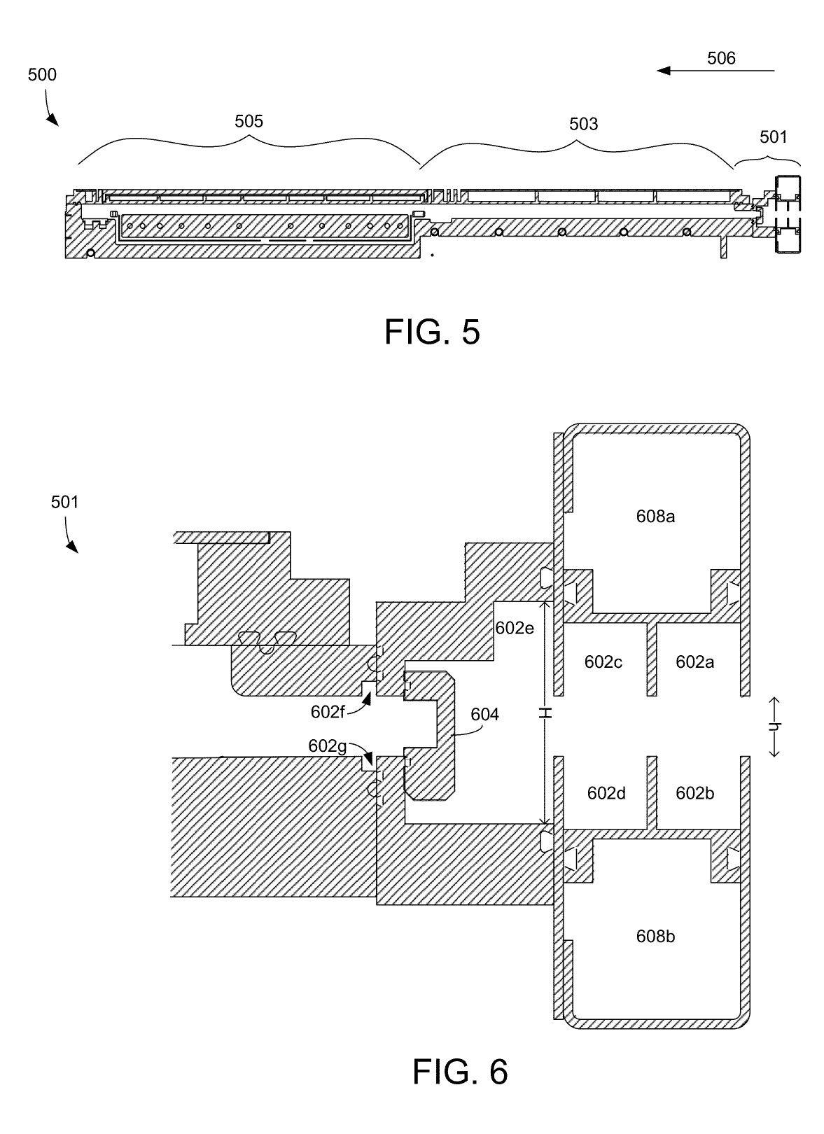

FIGS. 5-10 show different views of an embodiment of an anneal chamber having a wafer entry slit as disclosed herein. These figures use reference numbers that represent the same elements from one figure to the next. FIG. 5 shows a cross-sectional side view of an anneal chamber 500. The anneal chamber 500 includes an entry slit region 501, a cooling region 503, and a heating region 505. Arrow 506 indicates the direction in which a wafer is inserted into the anneal chamber 500. A transfer arm may be used to move the substrate between the entry slit and the cooling pedestal. An internal transfer arm (not shown) may transfer the substrate between the cooling pedestal and the heating station. In these embodiments, no load lock is used, and the anneal chamber does not vent hydrogen through the entry slit. Further, these embodiments include an exhaust mechanism to fully capture any escaping hydrogen.

FIG. 6 shows a close-up view of the entry slit region 501 of anneal chamber 500. The entry slit region 501 includes a plurality of cavities 602a-g, as well as rotatable door 604. The door 604 rotates/pivots downwards to allow a substrate to be inserted or removed. In FIG. 6, the door 604 is shown in a closed position. The entry slit region 501 has a certain minimum height, h, which represents the minimum distance between the upper and lower portions of the entry slit. While this minimum height is shown as the distance between the walls of cavities 602a-b (which also corresponds to the distance between several other top and bottom portions), this is not always the case. For example, if the space proximate the door is shorter, then the height of that region would determine the minimum height. The minimum height must be large enough to fit a substrate through horizontally. In some embodiments, the minimum height is at least about 8 mm, and may be between about 6-15 mm. This may correspond to a height that is between about 6×-15× thicker than the substrate thickness. Generally, shorter minimum heights provide better oxygen attenuation. However, shorter minimum heights also require more precise robots to transfer the substrates without damage. As such, the optimum minimum height may depend on the precision and geometry of available substrate handling methods.

The entry slit region 501 also has a maximum height, H, which corresponds to the greatest distance between the upper and lower portions of the entrance slit. This maximum height is typically fairly small, for example between about 2-5 cm. This may correspond to a maximum height that is no more than about 8.3× greater than the minimum height. This may also correspond to a maximum height that is at least about 1.3× greater than the minimum height.

Above and below cavities 602a-d are exhaust regions 608a-b. These exhaust regions 608a-b and cavities 602a-d may be implemented together on a separate piece of equipment (sometimes referred to as an exhaust shroud). Alternatively, these elements may be implemented directly in the anneal chamber entry slit. A vacuum is applied to the exhaust region, and gas present in cavities 602a-d may travel through small holes (not shown) to enter the exhaust region. This exhaust helps prevent introduction of oxygen into the anneal chamber, and also prevents forming gas from exiting the anneal chamber into the outer environment. In the embodiment shown here, the exhaust regions 608a-b act on four individual cavities 602a-d. In other embodiments, the exhaust regions may be coupled to at least about two cavities, at least about four cavities, or at least about six cavities. While only two cavities 602f-g are shown inward of the door 604, in other embodiments there are additional cavities in this region (i.e., between the cooling region of the anneal chamber and the door). For example, in some implementations there may be at least about two cavities, at least about four cavities, or at least about six cavities in this region.

FIG. 7 shows a close-up view of the entry slit region 501 of anneal chamber 500, with the door 604 shown in an open position. In this embodiment, the door 604 includes cavity 602h, which helps maintain the concentration of oxygen at a low level when a wafer is inserted into the chamber. The door 604 may also have slits 606, which may hold an o-ring or another type of seal. The cavities 602a-h shown in FIG. 7 are of non-uniform size. Cavities 602a-d are the largest, and cavities 602f-g are the smallest. In other embodiments the cavities may be more uniformly sized. Additionally, some embodiments employ an increased number of cavities. One way to introduce additional cavities is to include more cavities near the entrance/exhaust regions 608a-b. Another way is to introduce additional cavities in the area left of cavities 602f-g. Other options are available as well.

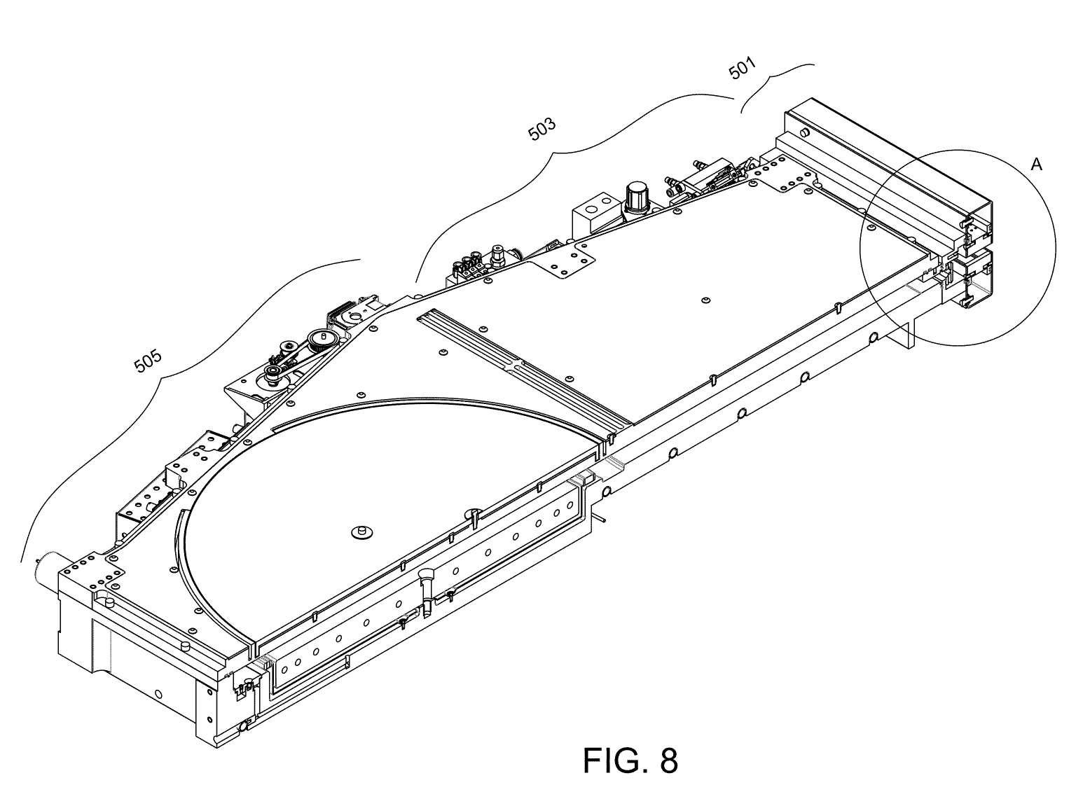

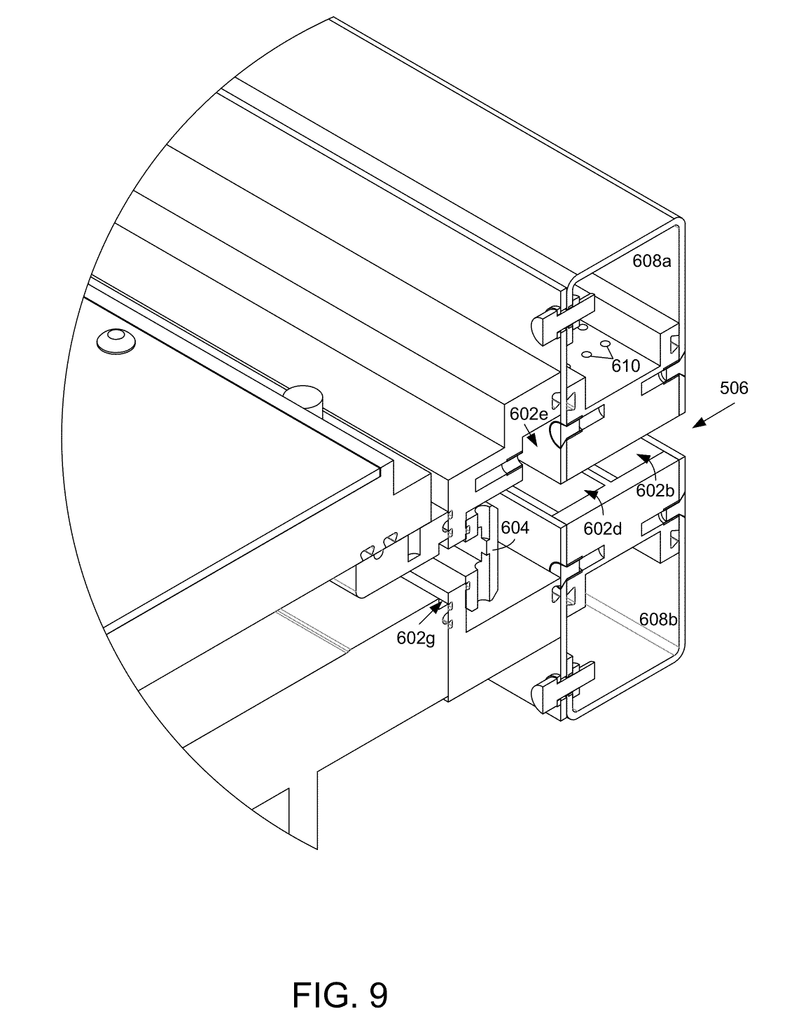

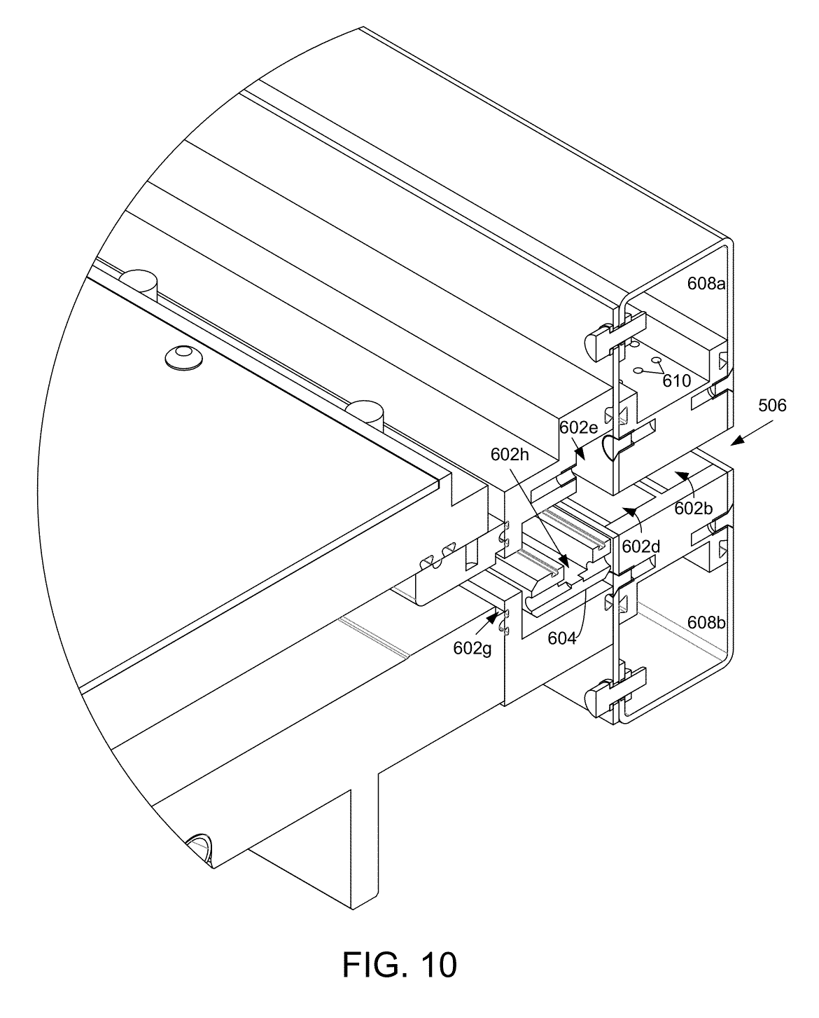

FIG. 8 shows a cut-away isometric view of anneal chamber 500 having entry slit portion 501, cooling portion 503 and heating portion 505. The circle marked “A” around the entry slit region 501 is shown in close-up view in FIGS. 9 and 10.

FIG. 9 shows a close-up view of the entry slit region 501 shown in FIG. 8. Certain reference numbers are included for context, while others are excluded for clarity. One feature that is shown in FIG. 9 which is not shown in previous drawings is the plurality of holes 610 that are situated between cavities 602a/602c and exhaust region 608a. Similar holes are provided between cavities 602b/602d and exhaust region 608b. These holes allow gas to be transported from the cavities 602a-d to the exhaust regions 608a-b, where the gas is carried away. The door 604 is shown in FIG. 9 in the down position. Arrow 506 shows the direction that the substrate travels during entry into the anneal chamber.

FIG. 10 shows a close-up view of the entry slit region 501 shown in FIGS. 8 and 9. The only difference between FIGS. 9 and 10 is that FIG. 10 shows the door 604 in the closed position.

Experimental results showing the effectiveness of the disclosed methods may be found below in the Experimental section.

The methods described herein may be performed by any suitable apparatus. A suitable apparatus includes a substrate entry slit having the hardware configurations disclosed herein. In some implementations, the hardware may include one or more process stations included in a process tool. In various cases, a suitable apparatus will also include a system controller having instructions for controlling process operations in accordance with the present embodiments.

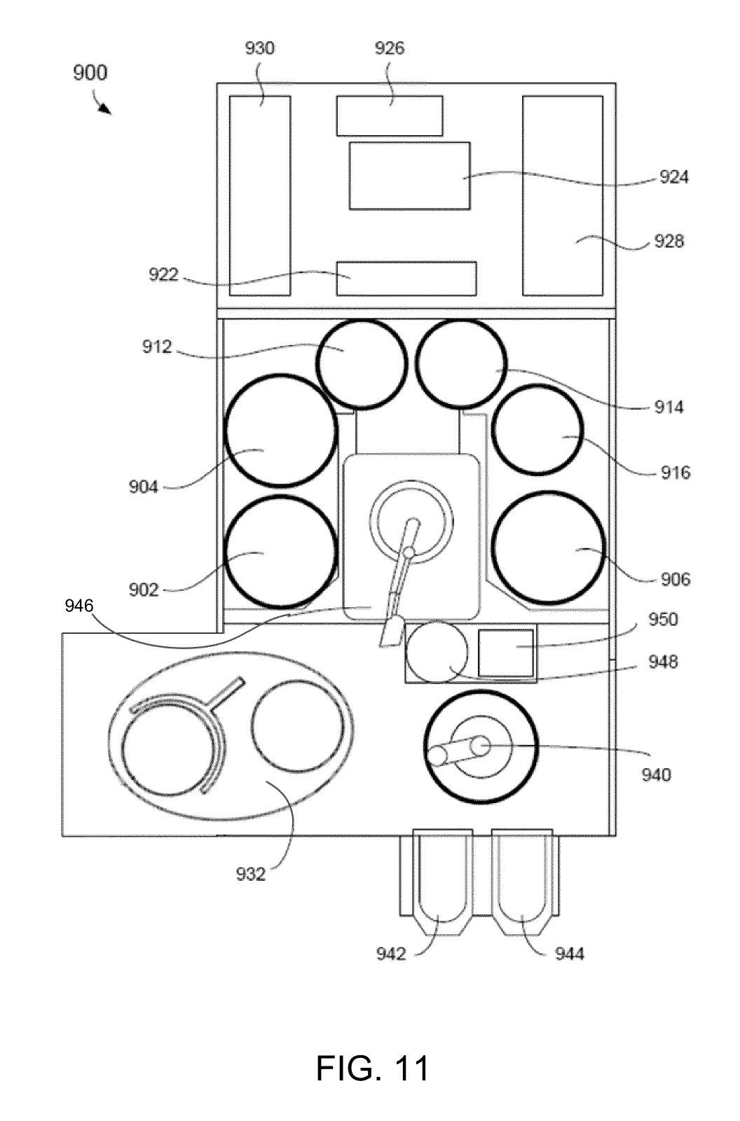

FIG. 11 shows an exemplary multi-tool apparatus that may be used to implement the embodiments herein. The electrodeposition apparatus 900 can include three separate electroplating modules 902, 904, and 906. The electrodeposition apparatus 900 can also include a stripping module 916. Further, two separate modules 912 and 914 may be configured for various process operations. For example, in some embodiments, one or more of modules 912 and 914 may be a spin rinse drying (SRD) module. In other embodiments, one or more of the modules 912 and 914 may be post-electrofill modules (PEMs), each configured to perform a function, such as edge bevel removal, backside etching, and acid cleaning of substrates after they have been processed by one of the electroplating modules 902, 904, and 906.

The electrodeposition apparatus 900 includes a central electrodeposition chamber 924. The central electrodeposition chamber 924 is a chamber that holds the chemical solution used as the electroplating solution in the electroplating modules 902, 904, and 906. The electrodeposition apparatus 900 also includes a dosing system 926 that may store and deliver additives for the electroplating solution. A chemical dilution module 922 may store and mix chemicals to be used as an etchant. A filtration and pumping unit 928 may filter the electroplating solution for the central electrodeposition chamber 924 and pump it to the electroplating modules. The electrodeposition apparatus 900 also includes an anneal chamber 932 which is configured as described herein.

A system controller 930 provides electronic and interface controls required to operate the electrodeposition apparatus 900. The system controller 930 (which may include one or more physical or logical controllers) controls some or all of the properties of the electroplating apparatus 900. The system controller 930 typically includes one or more memory devices and one or more processors. The processor may include a central processing unit (CPU) or computer, analog and/or digital input/output connections, stepper motor controller boards, and other like components. Instructions for implementing appropriate control operations as described herein may be executed on the processor. These instructions may be stored on the memory devices associated with the system controller 930 or they may be provided over a network. In certain embodiments, the system controller 930 executes system control software.

The system control software in the electrodeposition apparatus 900 may include instructions for controlling the timing, mixture of electrolyte components (including the concentration of one or more electrolyte components), inlet pressure, plating cell pressure, plating cell temperature, mixture of stripping solution components, removal cell temperature, removal cell pressure, substrate temperature, current and potential applied to the substrate and any other electrodes, substrate position, robot movement, substrate rotation, and other parameters of a particular process performed by the electrodeposition apparatus 900. In various cases the controller has instructions for inserting a substrate into a process chamber entry slit as disclosed herein. For example, the controller may have instructions to insert and/or remove a substrate at a relatively slow speed, supply forming gas to an anneal chamber (e.g., at a relatively high flow when an anneal chamber door is open and a relatively low flow when the door is closed), transfer the substrate between different portions of the anneal chamber, control the temperature in the anneal chamber, apply a vacuum to one or more cavities or surface vacuums in the entry slit, etc.

System control logic may be configured in any suitable way. For example, various process tool component sub-routines or control objects may be written to control operation of the process tool components necessary to carry out various process tool processes. System control software may be coded in any suitable computer readable programming language. The logic may also be implemented as hardware in a programmable logic device (e.g., an FPGA), an ASIC, or other appropriate vehicle.

In some embodiments, system control logic includes input/output control (IOC) sequencing instructions for controlling the various parameters described above. For example, each phase of an electroplating process may include one or more instructions for execution by the system controller 930. The instructions for setting process conditions for an anneal process phase may be included in a corresponding anneal recipe phase. In some embodiments, the electroplating recipe phases may be sequentially arranged, so that all instructions for an electroplating process phase are executed concurrently with that process phase.

The control logic may be divided into various components such as programs or sections of programs in some embodiments. Examples of logic components for this purpose include a substrate positioning/transfer component, an electrolyte composition control component, a stripping solution composition control component, a solution flow control component, a gas flow control component, a pressure control component, a heater control component, and a potential/current power supply control component. The controller may execute the substrate positioning component by, for example, directing the substrate holder to move (rotate, lift, tilt) as desired. Similarly, the controller may execute the substrate transfer component by directing appropriate robotic arms to move the substrate as desired between processing stations/modules/chambers. The controller may control the composition and flow of various fluids (including but not limited to electrolyte, stripping solution and forming gas) by directing certain valves to open and close at various times during processing. The controller may execute the pressure control program by directing certain valves, pumps and/or seals to be open/on or closed/off. Similarly, the controller may execute the temperature control program by, for example, directing one or more heating and/or cooling elements to turn on or off. The controller may control the power supply by directing the power supply to provide desired levels of current/potential throughout processing.

In some embodiments, there may be a user interface associated with the system controller 930. The user interface may include a display screen, graphical software displays of the apparatus and/or process conditions, and user input devices such as pointing devices, keyboards, touch screens, microphones, etc.

In some embodiments, parameters adjusted by the system controller 930 may relate to process conditions. Non-limiting examples include solution conditions (temperature, composition, and flow rate), substrate position (rotation rate, linear (vertical) speed, angle from horizontal, location with respect to different processing modules in a multi-tool apparatus) at various stages, etc. These parameters may be provided to the user in the form of a recipe, which may be entered utilizing the user interface.

Signals for monitoring the process may be provided by analog and/or digital input connections of the system controller 930 from various process tool sensors. The signals for controlling the process may be output on the analog and digital output connections of the process tool. Non-limiting examples of process tool sensors that may be monitored include mass flow controllers, pressure sensors (such as manometers), thermocouples, optical position sensors, etc. Appropriately programmed feedback and control algorithms may be used with data from these sensors to maintain process conditions.

In one embodiment of a multi-tool apparatus, the instructions can include inserting the substrate in a wafer holder, tilting the substrate, biasing the substrate during immersion, and electrodepositing a copper containing structure on a substrate. The instructions may further include transferring the substrate to an anneal chamber as disclosed herein.

A hand-off tool 940 may select a substrate from a substrate cassette such as the cassette 942 or the cassette 944. The cassettes 942 or 944 may be front opening unified pods (FOUPs). A FOUP is an enclosure designed to hold substrates securely and safely in a controlled environment and to allow the substrates to be removed for processing or measurement by tools equipped with appropriate load ports and robotic handling systems. The hand-off tool 940 may hold the substrate using a vacuum attachment or some other attaching mechanism.

The hand-off tool 940 may interface with an anneal chamber 932, the cassettes 942 or 944, a transfer station 950, or an aligner 948. From the transfer station 950, a hand-off tool 946 may gain access to the substrate. The transfer station 950 may be a slot or a position from and to which hand-off tools 940 and 946 may pass substrates without going through the aligner 948. In some embodiments, however, to ensure that a substrate is properly aligned on the hand-off tool 946 for precision delivery to an electroplating module, the hand-off tool 946 may align the substrate with an aligner 948. The hand-off tool 946 may also deliver a substrate to one of the electroplating modules 902, 904, or 906, or to the removal cell 916, or to one of the separate modules 912 and 914 configured for various process operations.

An apparatus configured to allow efficient cycling of substrates through sequential plating, rinsing, drying, and PEM process operations (such as stripping) may be useful for implementations for use in a manufacturing environment. To accomplish this, the module 912 can be configured as a spin rinse dryer and an edge bevel removal chamber. With such a module 912, the substrate would only need to be transported between the electroplating module 904 and the module 912 for the copper plating and EBR operations. Similarly, where the anneal chamber 955 is implemented on a multi-tool apparatus 900, substrate transfer between deposition and annealing processes is fairly simple.

In some embodiments, the electrodeposition apparatus may have a set of electroplating cells, each containing an electroplating bath, in a paired or multiple “duet” configuration. In addition to electroplating per se, the electrodeposition apparatus may perform a variety of other electroplating related processes and sub-steps, such as spin-rinsing, spin-drying, metal and silicon wet etching, electroless deposition, pre-wetting and pre-chemical treating, reducing, annealing, photoresist stripping, and surface pre-activation, for example. It is to be readily understood by one having ordinary skill in the art that such an apparatus, e.g. the Lam Research Sabre™ 3D tool, can have two or more levels “stacked” on top of each other, each potentially having identical or different types of processing stations.

Lithographic patterning of a film typically comprises some or all of the following steps, each step enabled with a number of possible tools: (1) application of photoresist on a workpiece, e.g., a substrate having a silicon nitride film formed thereon, using a spin-on or spray-on tool; (2) curing of photoresist using a hot plate or furnace or other suitable curing tool; (3) exposing the photoresist to visible or UV or x-ray light with a tool such as a wafer stepper; (4) developing the resist so as to selectively remove resist and thereby pattern it using a tool such as a wet bench or a spray developer; (5) transferring the resist pattern into an underlying film or workpiece by using a dry or plasma-assisted etching tool; and (6) removing the resist using a tool such as an RF or microwave plasma resist stripper. In some embodiments, an ashable hard mask layer (such as an amorphous carbon layer) and another suitable hard mask (such as an antireflective layer) may be deposited prior to applying the photoresist.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated may be performed in the sequence illustrated, in other sequences, in parallel, or in some cases omitted. Likewise, the order of the above described processes may be changed.

The subject matter of the present disclosure includes all novel and nonobvious combinations and sub-combinations of the various processes, systems and configurations, and other features, functions, acts, and/or properties disclosed herein, as well as any and all equivalents thereof.

### EXPERIMENTAL

Modeling results show that the disclosed embodiments are able to significantly reduce the concentration of oxygen in an anneal chamber. When conventional substrate entry slits are used, transient oxygen concentrations rise to over 400 ppm during substrate introduction/removal. With the disclosed embodiments, both steady state and transient oxygen concentrations may remain below about 1 ppm.

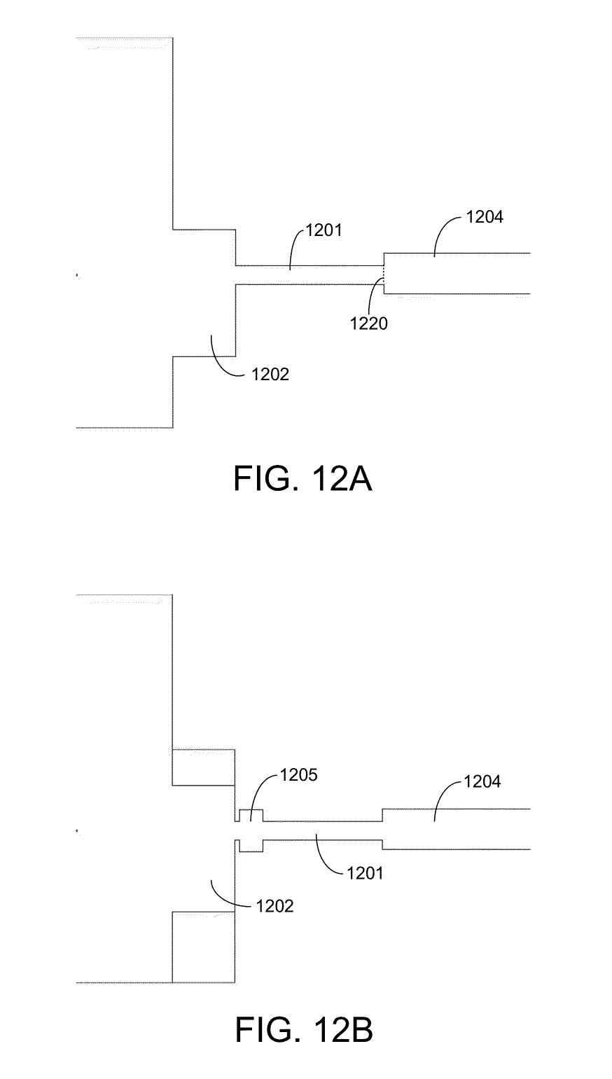

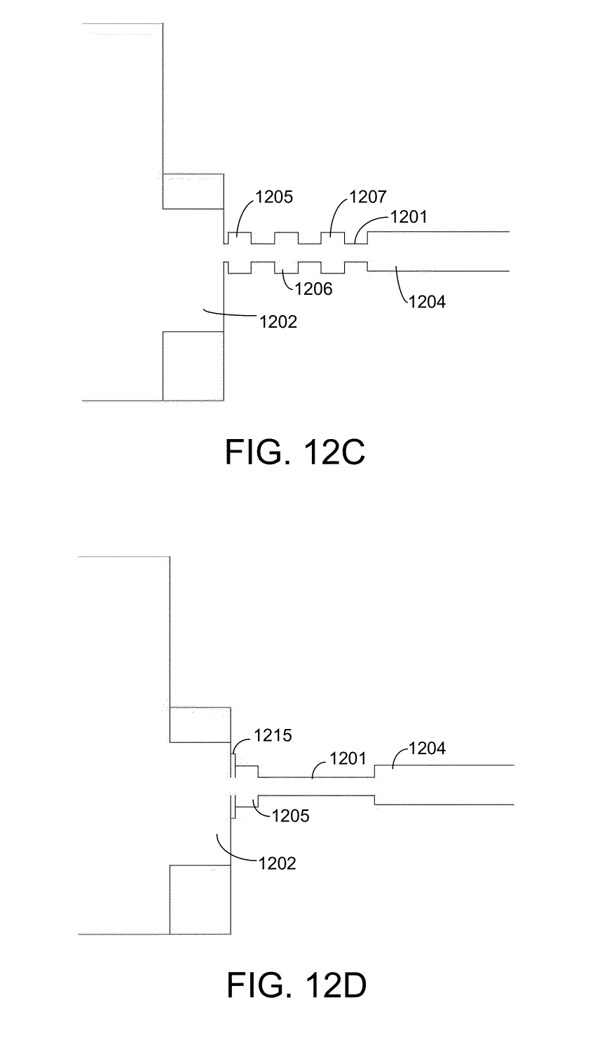

FIGS. 12A-12D present four alternative substrate entry slit configurations. These configurations are modeled to be fairly simple in order to understand the relative effect that the different elements (e.g., paired cavities, multiple paired cavities, and surface vacuums) have on the system. FIG. 12A shows a baseline conventional case where no cavities are used to attenuate oxygen concentration. FIG. 12B shows an embodiment where a single paired cavity is used. FIG. 12C shows an embodiment where three paired cavities are used. FIG. 12D presents an embodiment where a surface vacuum is used in conjunction with a single paired cavity.

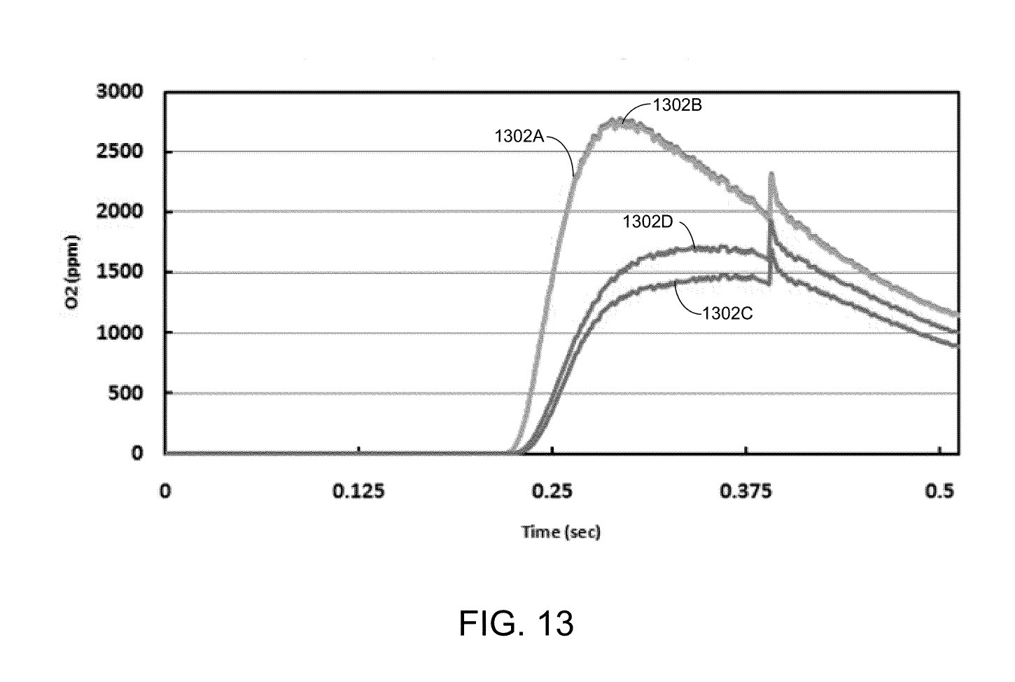

In 12A-12D, the substrate travels from left to right as it travels from the outer environment 1202, through the substrate entry slit 1201, and into the processing volume of the anneal chamber 1204. Where present, paired cavities 1205-1207 and surface vacuum 1215 operate to minimize the amount of oxygen that reaches the anneal chamber 1204. Other than the surface vacuum 1215 in FIG. 12D, no vacuum sources were included when modeling these configurations. Line 1220, seen in FIG. 12A, shows the location at which the oxygen concentration is modeled with regard to FIG. 13. This location is where the entry slit ends and the anneal chamber processing area begins. Although this line is only included with regard to FIG. 12A, it is understood that the other configurations were modeled at an identical location.

FIG. 13 shows the concentration of oxygen at the entry of the anneal chamber processing volume (i.e., at line 1220 of FIG. 12A) as a substrate is inserted through the entry slit. Because the models used in this exercise were simplified versions of the entry slits, the absolute values for oxygen concentration are not particularly important. Rather, these results are included to show the relative effectiveness of cavities, multiple cavities, and surface vacuums in minimizing oxygen levels in the anneal chamber. Lines 1302A-1302D correspond to the configurations shown in FIGS. 12A-12D, respectively. In other words, 1302A corresponds to the baseline case, 1302B corresponds to the single paired cavity case, 1302C corresponds to the multiple paired cavity case, and 1302D corresponds to the surface vacuum with single paired cavity case. The single paired cavity case 1302B showed a very slight improvement over the baseline case, 1302A. However, the improvement is so slight that the lines 1302A-1302B cannot be distinguished at this scale. The surface vacuum implementation 1302D showed a lot of improvement over the baseline and single paired cavity cases 1302A and 1302B. The greatest improvement (i.e., lowest peak transient oxygen concentrations) was seen in the multiple paired cavity case 1302C.

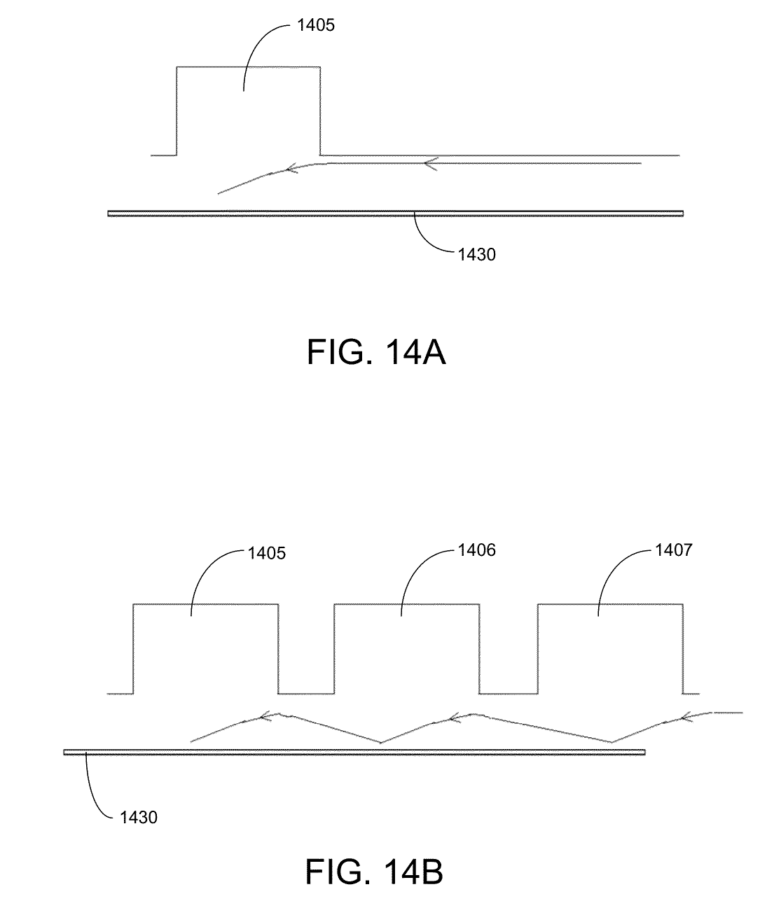

FIGS. 14A and 14B present rough diagrams of gas stream lines in a substrate entry slit in the case of a single cavity 1405 (FIG. 14A) and multiple cavities 1405-1406 (FIG. 14B). The arrow represents the flow path over the substrate 1430. It is believed that the use of multiple serially oriented cavities provides superior oxygen attenuation results because the multiple cavities offer additional opportunities to disrupt the boundary layer on the substrate 1430. This boundary layer disturbance helps to decrease the amount of oxygen that is carried into the processing volume of the anneal chamber.

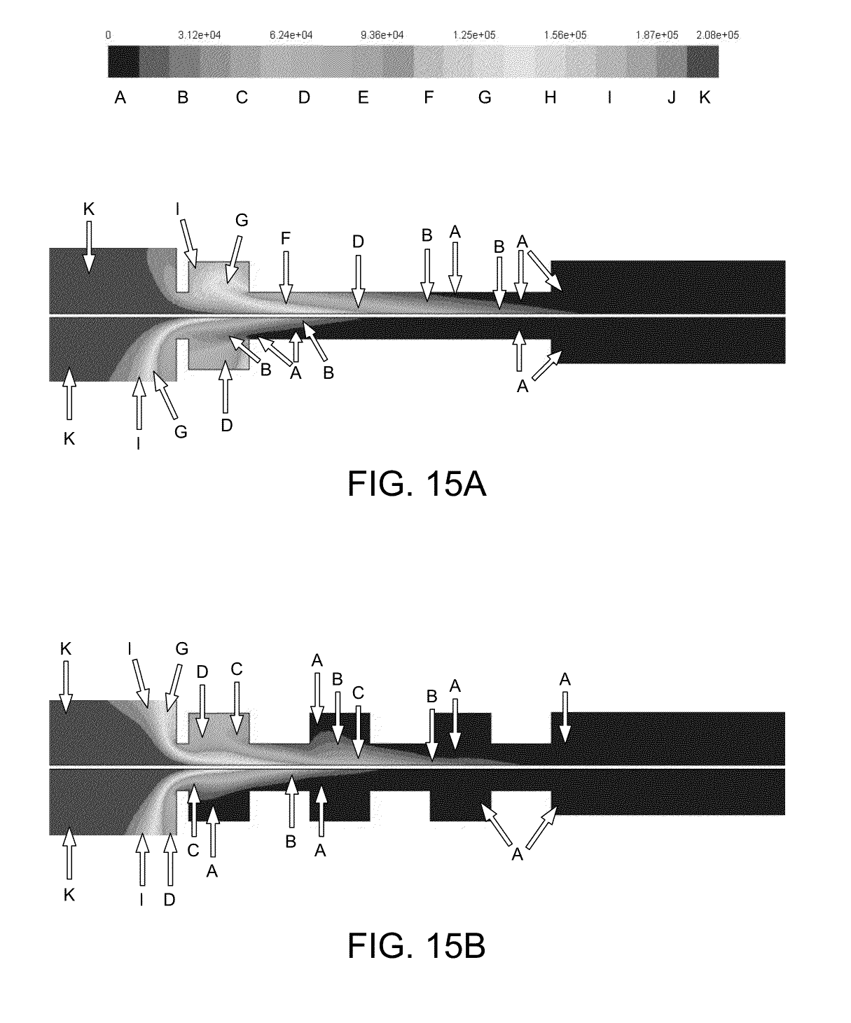

FIGS. 15A and 15B show modeling results regarding oxygen concentration contours in an entry slit/anneal chamber for a single paired cavity case (FIG. 15A) and a multiple paired cavity case (FIG. 15B). No surface vacuum or other vacuum source was included in the models. The legend provided applies to both figures. The legend is labeled with both numerical values representing the concentration of oxygen (in ppm), as well as letters. The letters are used to specify the oxygen concentration values at different positions in FIGS. 15A and 15B to provide a better understanding of the concentration profile. The letter A represents that there is substantially no oxygen present (about 0 ppm). Letters further in the alphabet correspond to higher oxygen concentrations, with K being the concentration of oxygen in the outer environment. The oxygen concentration is higher above the substrate as compared to below the substrate for both cases. This likely relates to the fact that a downwards gas flow is present in the outer environment. When taken together, FIGS. 15A and 15B show that the use of additional cavities results in extremely low oxygen concentrations inside the anneal chamber.

What is claimed is:

1. A processing chamber comprising:
an entry slit for transporting a thin substrate from an outer environment to the interior of the processing chamber and/or from the interior of the processing chamber to the outer environment, wherein the entry slit comprises an upper portion above the plane through which the substrate travels and a lower portion below the plane through which the substrate travels; and
a plurality of cavities in fluid communication with the entry slit, wherein at least three cavities are provided along at least one of the upper portion and lower portion of the entry slit.

2. The processing chamber of claim 1, wherein the entry slit has a minimum height of between about 6-14 mm.

3. The processing chamber of claim 1, wherein the entry slit has a minimum height less than about six times greater than the thickness of the substrate.

4. The processing chamber of claim 1, wherein the substrate comprises a 450 mm diameter semiconductor wafer.

5. The processing chamber of claim 1, wherein at least two cavities are provided in a paired cavity configuration.

6. The processing chamber of claim 1, wherein the entry slit further comprises an exhaust shroud comprising a vacuum source in fluid communication with the entry slit.

7. The processing chamber of claim 6, wherein at least three cavities are provided in the exhaust shroud.

8. The processing chamber of claim 1, wherein at least three cavities are provided in the entry slit at locations that are not part of an exhaust shroud.

9. The processing chamber of claim 1, wherein at least two cavities have different dimensions.

10. The processing chamber of claim 1, wherein the slit is at least about 1.5 cm long, as measured by the distance between the outer environment and the processing chamber.

11. The processing chamber of claim 1, wherein a distance between adjacent cavities on either the upper portion or lower portion of the entry slit is at least about 1 cm.

12. The processing chamber of claim 1, wherein the processing chamber is configured to maintain a maximum concentration of molecular oxygen below about 50 ppm, even during insertion and removal of the substrate.

13. The processing chamber of claim 1, wherein the processing chamber is an anneal chamber.

14. The processing chamber of claim 13, wherein the anneal chamber comprises a cooling station and a heating station.

15. The processing chamber of claim 1, wherein the entry slit further comprises a door having at least a first position and a second position.

16. The processing chamber of claim 15, wherein the door comprises at least one cavity that is in fluid communication with the entry slit when the door is in the first position.

17. The processing chamber of claim 1, wherein at least one of the cavities has a depth between about 2-20 mm.

18. The processing chamber of claim 1, wherein at least one of the cavities has a width between about 2-20 mm.

19. The processing chamber of claim 1, wherein at least one of the cavities has a substantially rectangular cross-section.

20. The processing chamber of claim 1, wherein at least one of the cavities has a non-rectangular cross-section.

21. A method of inserting a substrate from an outer environment into a processing chamber with minimal introduction of a gas of interest to the processing chamber, comprising:
inserting the substrate from the outer environment into an entry slit of a processing chamber, wherein the entry slit comprises an upper portion above a plane through which the substrate travels, a lower portion below the plane through which the substrate travels, and a plurality of cavities in fluid communication with the entry slit, wherein at least three cavities are provided on at least one of the upper and lower portions of the entry slit; and
transferring the substrate through the entry slit and into a processing volume of the processing chamber.

22. The method of claim 21, further comprising opening a door in or on the entry slit when a substrate is being actively transferred through the door, and closing the door when no such transfer is occurring.

23. The method of claim 22, further comprising flowing gas from the processing volume of the processing chamber at an increased gas flow at a time when the door is open, and flowing gas from the processing volume at a decreased gas flow at a time when the door is closed.

24. The method of claim 21, further comprising removing the substrate from the processing chamber at a slower rate than was used to insert the substrate into the processing chamber.

25. The method of claim 21, wherein the substrate is a 450 mm diameter substrate, and wherein the substrate is transferred in over a period of at least about 2 seconds.

26. The method of claim 21, wherein a maximum concentration of the gas of interest is maintained below about 350 ppm.

27. The method of claim 26, wherein the maximum concentration of the gas of interest is maintained below about 10 ppm.

28. The method of claim 21, wherein the processing chamber is an anneal chamber and the gas of interest is oxygen.
